(19) United States
(12) Patent Application Publication
(10) Pub. No.: US 2011/0159669 A1
(43) Pub. Date: Jun. 30, 2011

(54) METHOD FOR DEPOSITING AMORPHOUS SILICON THIN FILM BY CHEMICAL VAPOR DEPOSITION

(75) Inventors: Woo Seok Yang, Daejeon (KR); Seong mok Cho, Daejeon (KR); Ho Jun Ryu, Seoul (KR); Sang Hoon Cheon, Daejeon (KR); Byoung Gon Yu, Daejeon (KR); Chang Auck Choi, Daejeon (KR)

(73) Assignee: ELECTRONICS AND TELECOMMUNICATIONS RESEARCH INSTIT, Daejeon (KR)

(21) Appl. No.: 13/058,047

(22) PCT Filed: Sep. 18, 2009
(86) PCT No.: PCT/KR2009/005313

§ 371 Date: Feb. 8, 2011

(30) Foreign Application Priority Data
Sep. 19, 2008 (KR) 10-2008-0092080

(51) Int. Cl. H01L 21/20

(52) U.S. Cl. 438/482; 257/E21.09

(57) ABSTRACT

Provided is a method of depositing an amorphous silicon thin film by chemical vapor deposition (CVD) to prevent bubble defect occurring when an amorphous silicon thin film is deposited on a substrate contaminated by air exposure. The deposition method includes cleaning a surface of the contaminated substrate with a reaction gas activated by plasma and depositing an amorphous silicon thin film on the cleaned substrate. Here, a vacuum state is maintained from the substrate cleaning step to the thin film deposition step in order to prevent contamination of the surface of the cleaned substrate by re-exposure to air.

### TECHNICAL FIELD

The present invention relates to a method of depositing an amorphous silicon thin film by chemical vapor deposition, and more particularly, to a method of depositing an amorphous silicon thin film by chemical vapor deposition which may prevent a bubble defect formed by delamination during deposition of the thin film on a substrate contaminated by air exposure.

### BACKGROUND ART

Amorphous silicon is a main material applied in various electronic devices such as solar cells, thin film transistors (TFTs), image sensors and micro-electro-mechanical systems. To manufacture such electronic devices, a process of depositing an amorphous silicon thin film is in general performed on an air-exposed substrate after depositing or patterning another thin film.

An amorphous silicon thin film is usually deposited by chemical vapor deposition (CVD) such as plasma enhanced CVD (PECVD).

According to reference-1 (Theil et al., U.S. Pat. No. 6,436,488) and reference-2 (Li et al., U.S. Pat. No. 6,559,052), an amorphous silicon thin film was deposited on a substrate at 200 to 500° C. by an PECVD method using silicon hydride (e.g., SiH₄, Si₂H₆, Si₃H₈ or Si₄H₁₀) decomposed by plasma produced by supply of RF power. According to reference-1 and reference-2, diluting gas such as hydrogen (H₂) or an inactive gas (He, Ne, Ar, Kr or Xe), or a doping gas such as borane (BH₃), diborane (B₂H₅) or phosphine (PH₃), can be additionally used during the deposition.

According to reference-1, the amorphous silicon thin film is generally deposited by steps shown in FIG. 1. First, as shown in S10, a chamber inner wall is cleaned to prevent generation of particles during deposition of a thin film. Then, as shown in S12, the chamber inner wall is pre-coated with silicon nitride (Si₃N₄) or silicon oxide (SiO₂) to prevent a first wafer effect occurring in a batch-type process. That is, the pre-coating prevents deposition speed variation and particle generation caused by change in the state of the chamber inner wall from when a thin film is deposited on a first substrate to when a thin film is deposited on a second or later substrate. Next, the substrate is loaded into a chamber, a thin film is deposited on the substrate as shown in S14, and the substrate is taken out of the chamber.

According to reference-3 (Smith et al., U.S. Pat. No. 4,842,892; 1987), reference-4 (C. Yeh et al., Fabrication of Mechanical Microstructures Using Amorphous Silicon Film on Glass Substrates, MRS Proc. vol. 609, 2000) and reference-5 (C-K. Chung et al., Fabrication and Characterization of Amorphous Si Films by PECVD for MEMS, J. Micromech. Microeng. 15, 2004), when an amorphous silicon thin film is deposited on a silicon nitride, silicon oxide or silicon substrate by common chemical vapor deposition, a bubble defect formed by partial delamination of a thin film from the substrate may occur.

According to reference-3, when a silicon nitride thin film is deposited to a predetermined thickness or more on a silicon wafer, and an amorphous silicon layer is continuously deposited in a vacuum in the same chemical vapor deposition equipment, the bubble defect does not occur. This result shows that the bubble defect is caused by contaminants adsorbed on a surface of the air-exposed substrate.

According to reference-3, the bubble defect occurs only when an n+ amorphous silicon thin film doped with a large dose of phosphate (P) is deposited, and the cause of the bubble defect is interaction between a contaminant on the surface of the substrate and PH₃ gas for doping. Thus, when an undoped-amorphous silicon thin film is first deposited on a contaminated surface of the substrate only using SiH₄ gas, and an n+ amorphous silicon thin film is subsequently deposited using SiH₄ and PH₃ gases without a vacuum break, the bubble defect caused by delamination can be prevented.

However, according to reference-4, reference-5 and experiments conducted by the present inventor, the bubble defect also occurs when an undoped amorphous silicon thin film is deposited using only SiH₄ gas and no PH₃ gas. Thus, it is confirmed that the bubble defect occurring when an amorphous silicon thin film is deposited on a contaminated silicon, silicon nitride or silicon oxide substrate cannot be prevented by the conventional method of chemical vapor deposition.

### DISCLOSURE OF INVENTION

### Technical Problem

The present invention is directed to a deposition method which can effectively prevent a bubble defect due to partial delamination caused when an amorphous silicon thin film is deposited by chemical vapor deposition on a substrate whose surface is contaminated by air exposure.

### Solution to Problem

One aspect of the present invention provides a method of depositing an amorphous silicon thin film by chemical vapor deposition, including: loading a substrate contaminated by air exposure into a reaction chamber; cleaning a surface of the substrate with a reaction gas activated by plasma; and depositing an amorphous silicon thin film on the cleaned substrate, wherein a vacuum state is maintained from the substrate cleaning step to the thin film deposition step.

Another aspect of the present invention provides a method of depositing an amorphous silicon thin film by chemical vapor deposition, including: loading a substrate contaminated by air exposure into a first reaction chamber; cleaning a surface of the substrate with a reaction gas activated by plasma; loading the cleaned substrate into a second reaction chamber; and depositing an amorphous silicon thin film on the cleaned substrate, wherein a vacuum state is maintained from the substrate cleaning step to the thin film deposition step.

In the deposition method according to the present invention, a surface of the substrate may include silicon (Si), silicon nitride (Si₃N₄), silicon oxide (SiO₂), or another nitrides or oxides.

In the deposition method according to the present invention, the reaction gas activated by plasma for substrate cleaning may be oxygen (O₂) or ammonia (NH₃) gas.

In the deposition method according to the present invention, the substrate may be cleaned at a substrate temperature of 200 to 500° C., a gas flow of 100 to 500 sccm, a chamber pressure of 0.5 to 3 Torr, and an RF power of 0.3 to 1.5 W/cm², for 1 to 5 minutes.

In the deposition method according to the present invention, the amorphous silicon may be deposited using silicon hydride (SiH₄, Si₂H₆, Si₃H₈ or Si₄H₁₀).

In the deposition method according to the present invention, the amorphous silicon may be deposited using silicon hydride (SiH₄, Si₂H₆, Si₃H₈ or Si₄H₁₀) including a doping gas.

In the deposition method according to the present invention, the thin film deposition may be performed at a substrate temperature of 200 to 500° C.

### Advantageous Effects of Invention

According to a method of depositing an amorphous silicon thin film by chemical vapor deposition according to the present invention, a bubble defect due to partial delamination occurring when an amorphous silicon thin film is deposited on a substrate contaminated by air exposure can be effectively prevented, and thus yields of various electronic devices manufactured using amorphous silicon can be increased.

### BRIEF DESCRIPTION OF DRAWINGS

The above and other objects, features and advantages of the present invention will become more apparent to those of ordinary skill in the art by describing in detail exemplary embodiments thereof with reference to the accompanying drawings, in which

FIG. 1 is a flowchart of a conventional chemical vapor deposition process of an amorphous silicon thin film;

FIG. 2 is a flowchart of a method of depositing an amorphous silicon thin film for preventing a bubble detect generated when an amorphous silicon thin film is deposited according to an exemplary embodiment of the present invention;

FIG. 3 is a flowchart of a method of depositing an amorphous silicon thin film for preventing a bubble defect generated when an amorphous silicon thin film is deposited according to another exemplary embodiment of the present invention;

FIG. 4 is an optical microscopic photograph showing an example of a bubble defect due to delamination during deposition of an amorphous silicon thin film by conventional chemical vapor deposition;

FIG. 5 is an optical microscopic photograph showing a surface of the amorphous silicon thin film deposited according to an exemplary embodiment of the present invention; and

FIG. 6 is an optical microscopic photograph showing a surface of the amorphous silicon thin film deposited according to another exemplary embodiment of the present invention.

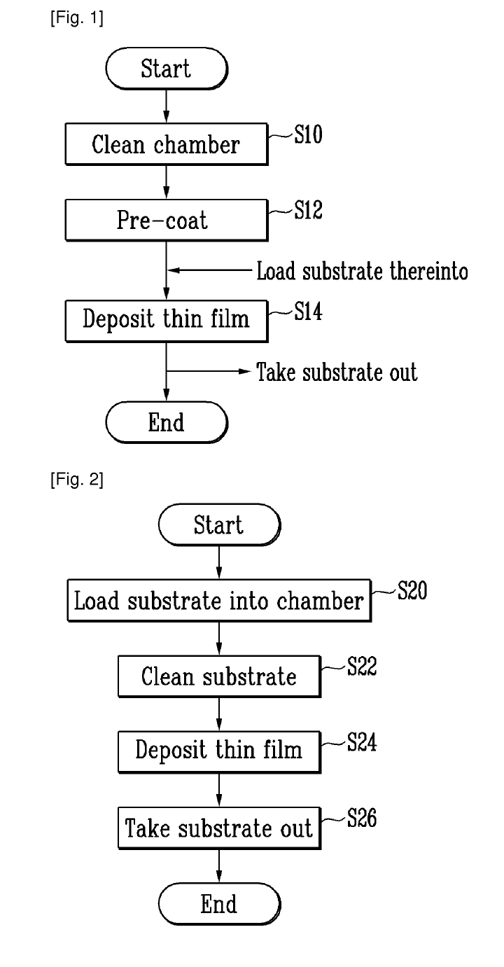

### MODE FOR THE INVENTION

Hereinafter, exemplary embodiments of the present invention will be described in detail. However, the present invention is not limited to the exemplary embodiments disclosed below, but can be implemented in various modified forms. The present exemplary embodiments are provided to fully enable those of ordinary skill in the art to embody and practice the invention.

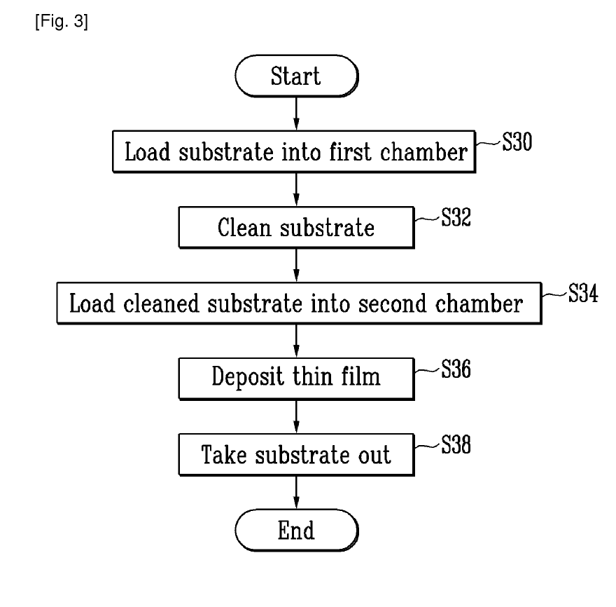

FIG. 2 is a flowchart of a method of depositing an amorphous silicon thin film by chemical vapor deposition according to an exemplary embodiment of the present invention, and FIG. 3 is a flowchart of a method of depositing an amorphous silicon thin film by chemical vapor deposition according to another exemplary embodiment of the present invention.

Referring to FIG. 2, a method of depositing an amorphous silicon thin film by chemical vapor deposition according to the present invention includes loading a substrate into a chamber (S20), cleaning the substrate (S22), depositing a thin film (S24) and taking the substrate out of the chamber (S26), which are sequentially performed.

Before loading the substrate into the chamber (S20), the chamber may be pretreated by cleaning and coating.

The chamber cleaning is to prevent generation of particles by etching the amorphous silicon thin film which can be excessively deposited on an inner wall of the chamber using a fluorine-containing gas (e.g., CF₄, C₂F₆, C₃F₈, CHF₃, NF₃ or SF₆).

The coating is to reduce a first wafer effect occurring in a batch-type process by depositing amorphous silicon on the inner wall of the chamber to a predetermined thickness using silicon hydride (e.g., SiH₄, Si₂H₆, Si₃H₈ or Si₄H₁₀).

Afterward, the substrate is loaded into the chamber (S20). Here, a surface of the substrate includes silicon, silicon nitride, silicon oxide, or another nitrides or oxides. When an amorphous silicon film is deposited on these materials without cleaning of the substrate, a bubble defect occurs. However, when an amorphous silicon thin film is deposited on metal, e.g., aluminum (Al) or chromium (Cr), or an organic material such as polyimide, without cleaning the substrate, the bubble defect does not occur.

In cleaning the substrate (S22), a contaminant on the surface of the substrate is removed by reaction with oxygen (O₂) or ammonia (NH₃) gas activated by plasma when RF power is applied. Here, the cleaning may be conducted at a temperature of 200 to 500° C., a gas flow of 100 to 500 sccm, a chamber pressure of 0.5 to 3 Torr, an RF power of 0.3 to 1.5 W/cm², and a reaction time of 1 to 5 minutes.

In depositing the thin film (S24), an amorphous silicon thin film is deposited on the surface of the cleaned substrate using silicon hydride (SiH₄, Si₂H₆, Si₃H₈ or Si₄H₁₀) or silicon hydride (SiH₄, Si₂H₆, Si₃H₈ or Si₄H₁₀) including a doping gas. Here, PH₃ may be used as a doping gas.

Here, the deposition may be performed at a temperature of 200 to 500° C., a gas flow of 20 to 60 sccm, a chamber pressure of 0.5 to 1.5 Torr, and an RF power of 0.1 to 0.3 W/cm².

Subsequently, the substrate having the deposited amorphous silicon thin film is taken out of the chamber (S26).

The deposition of the thin film (S26) may be performed in the same chamber where the cleaning of the substrate was previously performed, as shown in FIG. 2, or in a different chamber for stabilization of characteristics of the deposited amorphous silicon thin film, as shown in FIG. 3.

That is, referring to FIG. 3, a method of depositing an amorphous silicon thin film by chemical vapor deposition according to the present invention includes loading a substrate into a first reaction chamber (S30), cleaning a substrate (S32), loading the cleaned substrate into a second reaction chamber (S34), depositing a thin film (S36) and taking the substrate out of the chamber (S38).

In the process shown in FIG. 3, a pretreatment step including cleaning and coating of a chamber may be preferably performed in the second reaction chamber, which is a deposition chamber.

The other steps may be performed the same as shown in FIG. 2.

In either process performed in one or two chambers, the cleaning to deposition steps have to be performed without a vacuum break. Thus, a separate load-lock chamber may be used to prevent air exposure and resulting contamination of the reaction chamber where the cleaning of the substrate and the deposition of the thin film are performed when the substrate is loaded into the chamber. That is, in the case of using one chamber, a substrate is loaded into a load-lock chamber at atmospheric pressure, the load-lock chamber is pumped to vacuum pressure, and then the substrate is transferred from the load-lock chamber to a reaction chamber in a vacuum. In the case of using two chambers, a substrate is loaded into a load-lock chamber at atmospheric pressure, the load-lock chamber is pumped to vacuum pressure, and then the substrate is transferred from the load-lock chamber to a first chamber and then to a second chamber in a vacuum.

### Comparative Example

A silicon nitride (Si₃N₄) thin film was deposited on a silicon wafer to a thickness of 100 nm and exposed to air for 5 minutes. Then, an amorphous silicon thin film was deposited to a thickness of 150 nm using SiH₄ gas. Here, the deposition of the amorphous silicon thin film was performed at a substrate temperature of 400° C., a gas flow of 30 sccm, a chamber pressure of 1.2 Torr, and an RF power of 0.1 W/cm², for 4 minutes.

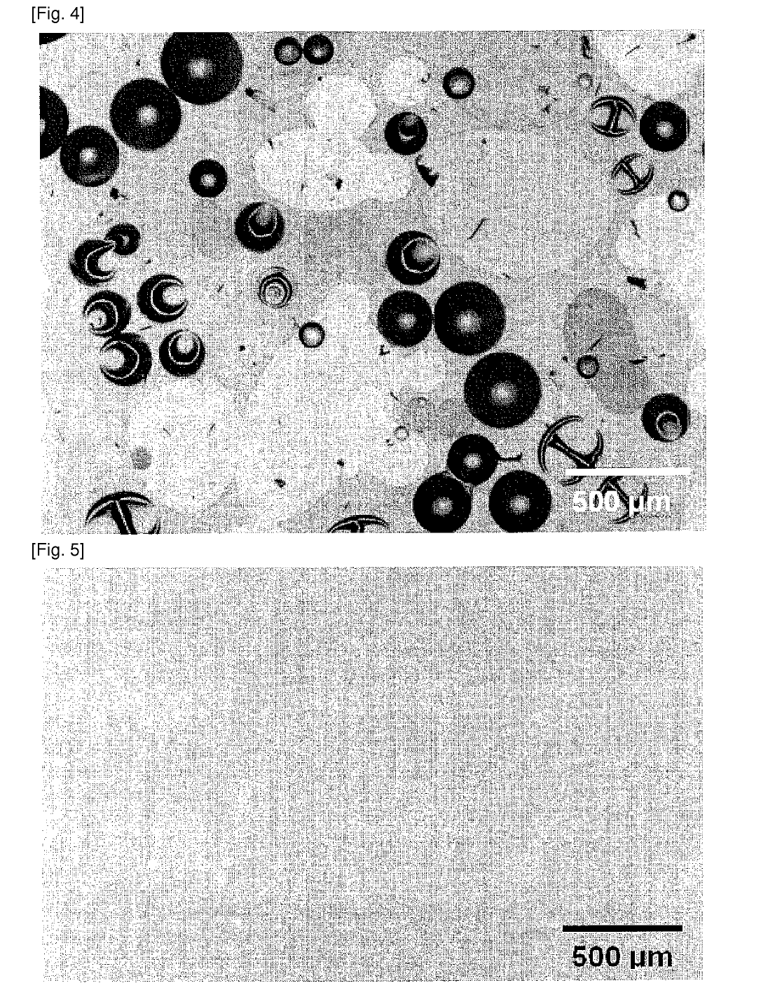

Subsequently, the deposited surface of the substrate was imaged by using optical microscopy, and the result is shown in shown in FIG. 4. FIG. 4 shows that a hemispherical bubble defect having a diameter of several tens of μm to several mm was generated, and it was distorted or completely delaminated to expose an underlying layer or a substrate as an inner gas leaked out.

### Example 1

A silicon nitride (Si₃N₄) thin film was deposited on a silicon wafer to a thickness of 100 nm and exposed to air for 5 minutes. Then, the silicon wafer was introduced into a chamber cleaned with a fluorine-containing gas and coated with amorphous silicon deposited to a thickness of 150 nm using SiH₄, and cleaned with ammonia (NH₃) gas activated by plasma due to supply of RF power. Here, the cleaning was performed at a substrate temperature of 400° C., a gas flow of 100 sccm, a chamber pressure of 0.8 Torr, and an RF power of 0.3 W/cm², for 5 minutes. Subsequently, an amorphous silicon thin film was subsequently deposited to a thickness of 150 nm using SiH₄ gas without a vacuum break. Here, the deposition of the amorphous silicon thin film was performed at a substrate temperature of 400° C., a gas flow of 30 sccm, a chamber pressure of 1.2 Torr, and an RF power of 0.1 W/cm², for 4 minutes.

Finally, the deposited surface of the substrate was imaged by using optical microscopy, and the result is shown in shown in FIG. 5.

### Example 2

A silicon nitride (Si₃N₄) thin film was deposited on a silicon wafer to a thickness of 100 nm and exposed to air for 5 minutes. Then, the silicon wafer was introduced into a chamber cleaned with a fluorine-containing gas and coated with amorphous silicon deposited to a thickness of 150 nm using SiH₄, and cleaned with ammonia (NH₃) gas activated by plasma due to supply of RF power. Here, the cleaning was performed at a substrate temperature of 400° C., a gas flow of 100 sccm, a chamber pressure of 0.8 Torr, and an RF power of 0.3 W/cm², for 5 minutes. Subsequently, an amorphous silicon thin film was deposited to a thickness of 150 nm using SiH₄ gas including PH₃ without a vacuum break. Here, the deposition of the amorphous silicon thin film was performed at a substrate temperature of 400° C., a SiH₄ gas flow of 30 sccm, a flow of 1.5% PH₃ gas diluted in H₂ of 60 sccm, a chamber pressure of 1.2 Torr, and an RF power of 0.1 W/cm², for 4 minutes.

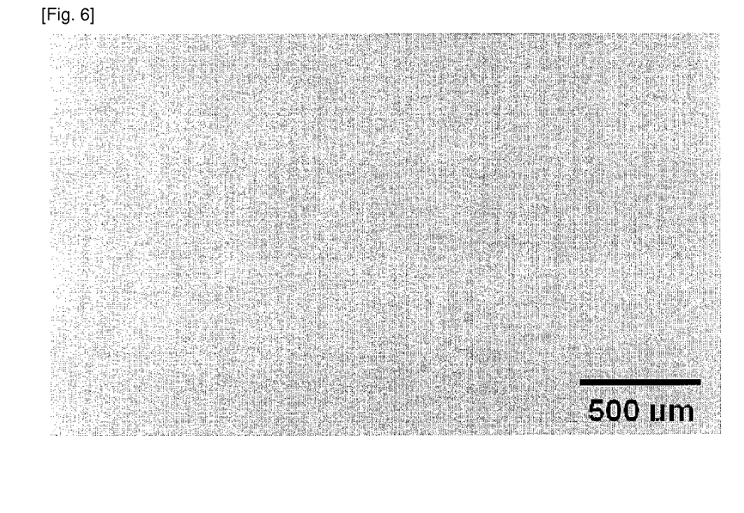

Finally, the deposited surface of the substrate was imaged by using optical microscopy, and the result is shown in shown in FIG. 6.

Comparing the optical microscope images of the deposition surfaces of the Comparative Example and Examples 1 and 2, it can be confirmed that the bubble defect was prevented more in Examples 1 and 2 than in the Comparative Example.

While the invention has been shown and described with reference to certain exemplary embodiments thereof, it will be understood by those skilled in the art that various changes in form and details may be made therein without departing from the spirit and scope of the invention as defined by the appended claims.

1. A method of depositing an amorphous silicon thin film by chemical vapor deposition, comprising:
loading a substrate contaminated by air exposure into a reaction chamber;
cleaning a surface of the substrate with a reaction gas activated by plasma; and
depositing an amorphous silicon thin film on the cleaned substrate, wherein a vacuum state is maintained from the substrate cleaning step to the thin film deposition step.

2. The method according to claim 1, wherein the surface of the substrate includes silicon (Si), silicon nitride (Si₃N₄), silicon oxide (SiO₂), or another nitrides or oxides.

3. The method according to claim 1, wherein the reaction gas activated by plasma while cleaning the substrate includes oxygen (O₂) or ammonia (NH₃) gas.

4. The method according to claim 1, wherein the substrate is cleaned at a substrate temperature of 200 to 500° C., a gas flow of 100 to 500 sccm, a chamber pressure of 0.5 to 3 Torr, and an RF power of 0.3 to 1.5 W/cm², for 1 to 5 minutes.

5. The method according to claim 1, wherein in deposition the thin film, the amorphous silicon is deposited using silicon hydride (SiH₄, Si₂H₆, Si₃H₈ or Si₄H₁₀).

6. The method according to claim 1, wherein in depositing the thin film, the amorphous silicon is deposited using silicon hydride (SiH₄, Si₂H₆, Si₃H₈ or Si₄H₁₀) including a doping gas.

7. The method according to claim 1, wherein in depositing the thin film, a temperature of the substrate is 200 to 500° C.

8. A method of depositing an amorphous silicon thin film by chemical vapor deposition, comprising:
loading a substrate contaminated by air exposure into a first reaction chamber;
cleaning a surface of the substrate with a reaction gas activated by plasma;
loading the cleaned substrate into a second reaction chamber; and
depositing an amorphous silicon thin film on the cleaned substrate, wherein a vacuum state is maintained from the substrate cleaning step to the thin film deposition step.

9. The method according to claim 8, wherein the surface of the substrate includes silicon (Si), silicon nitride (Si₃N₄), silicon oxide (SiO₂), or another nitrides or oxides.

10. The method according to claim 8, wherein the reaction gas activated by plasma while cleaning the substrate includes oxygen (O₂) or ammonia (NH₃) gas.

11. The method according to claim 8, wherein the substrate is cleaned at a substrate temperature of 200 to 500° C., a gas flow of 100 to 500 sccm, a chamber pressure of 0.5 to 3 Torr, and an RF power of 0.3 to 1.5 W/cm², for 1 to 5 minutes.

12. The method according to claim 8, wherein in deposition the thin film, the amorphous silicon is deposited using silicon hydride (SiH₄, Si₂H₆, Si₃H₈ or Si₄H₁₀).

13. The method according to claim 8, wherein in depositing the thin film, the amorphous silicon is deposited using silicon hydride (SiH₄, Si₂H₆, Si₃H₈ or Si₄H₁₀) including a doping gas.

14. The method according to claim 8, wherein in depositing the thin film, a temperature of the substrate is 200 to 500° C.
